(19) United States
(12) Patent Application Publication
(10) Pub. No.: US 2024/0048074 A1
(43) Pub. Date: Feb. 8, 2024

(54) DRIVE DEVICE AND METHOD FOR OPERATING A DRIVE DEVICE OF THIS TYPE

(71) Applicant: PHYSIK INSTRUMENTE (PI) GMBH & CO. KG, Karlsruhe (DE)

(72) Inventor: Waldemar SPOMER, Baden-Baden (DE)

(21) Appl. No.: 18/267,126

(22) PCT Filed: Dec. 10, 2021
(86) PCT No.: PCT/DE2021/100994

§ 371 Date: Jun. 14, 2023

(30) Foreign Application Priority Data
Dec. 15, 2020 (DE) 102020133455.9

(51) Int. Cl. H02N 2/02

(52) U.S. Cl. CPC H02N 2/023

(57) ABSTRACT

The invention relates to a drive device (1) comprising at least one drive unit (2) with at least one first and one second drive element (20), and a runner (3) which is to be moved in a drive direction by way of the drive unit (2), wherein each drive element (20) comprises a base element (210) and at least three actuators (200) which are arranged on the base element (210) so as to lie next to one another in an arrangement direction which lies transversely with respect to the drive direction, and wherein at least one of the actuators (200) of a drive element (20) has a shear section (220) for carrying out a shear movement transversely with respect to the arrangement direction of the actuators (200) and along the drive direction of the runner (3), and at least one of the actuators (200) of a drive element (20) has a stroke section (240) for carrying out a stroke movement transversely with respect to the arrangement direction of the actuators (200) and transversely with respect to the drive direction of the runner (3), and wherein the at least two drive units (2) are arranged so as to lie behind one another along the drive direction of the runner (3). In addition, the invention relates to a method for operating a drive device (1) of this type.

### CLAIM TO PRIORITY

This application claims priority to and the benefit of the following pending application PCT/DE2021/100994 having an International filing date 2021 Dec. 10 which claims priority to Priority Application No. DE 102020133455.9 having a priority date of 2020 Dec. 15

### FIELD OF INVENTION

The invention relates to a drive device according to claim 1 and to a method for operating such a drive device according to claims 11 and 12

### BACKGROUND

From the EP 1 267 478 B1 going back to the applicant, a so-called walk drive is known, in which in the exemplary embodiments according to FIGS. 1 and 3 there is disclosed a drive module with a total of four piezoelectric actors arranged next to one another or one behind the other on a substrate. Each actor is designed as a hybrid actor and comprises a stroke section adjacent to the substrate and at least one shear section which adjoins the stroke section in a direction along the extension direction of the actor. The four actors comprise a linear arrangement with respect to one another, wherein the linear arrangement defines a corresponding arrangement direction which coincides with the drive direction of the element to be driven.

By suitable simultaneous electrical actuation of the two sections of each actor, a defined trajectory of the freely movable end section of the respective actor, which preferably comprises a circular or elliptical shape, can be achieved based on a superposition of the stroke movement of the stroke section and the shear movement of the shear section. As a result, the respective actor temporarily comes into contact with an element to be driven and causes a single drive step during the corresponding contact or drive phase.

The four actors of the drive unit can be divided into two groups in each case of two actors, so that two distinguishable actor pairs are present. The actors of one or the same pair of actors are controlled in-phase, while the actors of different actor pairs are controlled in a phase-shifted manner with respect to one another. As a result of the phase-shifted control of the two actor pairs, temporally successive contact between the two pairs of actors and the element to be driven can be realized in-phase-shifted control of the two pairs of actors. In other words, the two actor pairs ensure a drive phase or a drive step of the element to be driven, and by corresponding repetition, a sequence of individual drive steps results, which ultimately leads to a substantially continuous movement of the element to be driven.

After an actor pair has passed through a drive phase or has completed a drive step as described above, it passes through a return movement or return phase, in which it is moved to a position from where a renewed drive phase can be started. In this return phase, it makes a movement which is directed substantially away from the runner, as a result of which a lifting off of this or an out-of-contact with the runner is to be achieved.

Against the background that the stroke sections, in particular in the case of miniaturized drives, can execute only the smallest stroke movements which lie in the region of the manufacturing tolerances with respect to the intended actor height (desired height), it is necessary for reliable contact of the individual actors with the element to be driven at least during the drive phase to press the substrate and thus also the actors attached thereto with a certain force in the direction of the element to be driven. This is usually done with a spring element which engages the substrate (not shown in EP 1 267 478 B1). However, even high spring forces are not sufficient for larger deviations from the target height of the actors under certain circumstances that all actors come into sufficient engagement with the element to be driven. On the other hand, high spring forces, under certain circumstances, result in that individual or all actors do not stroke off or only insufficiently stroke off from the element to be driven during the return phase, which can lead to increased wear of the drive or reduced drive force.

Furthermore, the walk drive of EP 1 267 478 B1 has certain disadvantages due to the self-height of the actors with regard to applications in which a small dimension is required, in particular with respect to the height.

It is therefore an object of the invention to provide a drive device which, in particular with regard to its height, can be constructed in a very compact manner, and which makes it possible, on account of its structure, to realize reliable and defined contact conditions between the driving actors and the element to be driven.

### SUMMARY

This object is achieved with a drive device according to claim 1, wherein at least expedient developments thereof are the subject-matter of the dependent claims.

The drive device according to the invention comprises at least one base, at least one drive unit arranged on the base or connected thereto, and a runner to be driven by the drive unit along a movement direction. In this case, the movement direction preferably runs along a straight line, so that a linear drive device may be provided, but also movement directions along a curved line, for example in the case of a rotary drive device, are conceivable.

The drive unit comprises at least two drive elements, wherein each drive element comprises a separate base element which belongs to the drive element and at least two actors which are arranged one behind the other on the base element along an arrangement direction oriented transversely to the movement direction of the runner and which are preferably arranged one behind the other along a direction transverse to the movement direction of the runner and preferably in a mutual overlap, whose dimensions can be changed by an electrical control and of which at least one forms a contact actor which is provided for frictional contact with the runner. The base element of each drive element is disposed opposite the base and spaced apart from the base so that the actors are disposed between the respective base element and the base.

The term “dimensionally changeable actor” means actors in which at least one dimension, for example the height, the length, the width, the thickness etc., can be changed at least in a section by electrical control.

At least one of the actors of a drive element comprises a shear section for carrying out a shear movement transverse to the arrangement direction of the actors and along or parallel to the movement direction of the runner. It is conceivable here that an actor is designed, for example, as a stack comprising a section for generating a lift movement and a section for generating a shear movement. It is also conceivable that an actor of the drive element has, in addition to a stroke section, two different shear sections, wherein the shear movements of the two shear sections differ from one another. Preferably, the shear section concerns the entire actor so that the actor constitutes a shear actor.

Furthermore, at least one of the actors of a drive element comprises a stroke section for carrying out a lift movement transverse to the arrangement direction of the actors and transversely to the movement direction of the runner. Here, too, it is conceivable for the corresponding actor to comprise at least one shear section in addition to the stroke section. The stroke section preferably concerns the entire actor, so that the actor constitutes a stroke actor.

In the case of a drive device having two or more than two drive units, they are arranged one behind the other along the movement direction or drive direction of the runner and are preferably arranged in mutual overlap to one another.

Due to the side-by-side, linear arrangement of the actors of a drive unit and the possibility of distributing the stroke and shear function to the individual actors or actor sections, each of the actors can have a comparatively small height, so that the drive unit and thus the entire drive device can be realized in a very compact manner, in particular with respect to their height extent.

In addition, a distribution of the stroke and shear function to the corresponding actors of a drive unit makes it possible, in the case of a plurality of drive units, to apply a separate pretensioning force to each individual drive unit of the drive units arranged one behind the other along the movement direction or drive direction of the runner, which presses the respective drive unit with a well-defined force against the runner or in a direction towards the runner. In this case, the pretensioning force should on the one hand be so large that the actor provided for contact with the runner, i.e. the contact actor, reliably contacts the runner during the drive phase even in the case of relatively large deviations from a specified height, and on the other hand should be so small that a defined lifting of the contact actor during the return phase or the return movement is ensured.

It may be advantageous if at least three actors are arranged along a row or linearly on the base element and the two actors of each drive element which lie outer with respect to the arrangement direction comprise a stroke section or are designed as a stroke actor and the at least one contact actor arranged between the outer actors comprises a shear section or is designed as a shear actor. In this case, the actors comprising the stroke section or the stroke actors ensure, by a corresponding dimensional change, a stroking of the at least one shear actor or the at least one actor comprising a shear section from the element to be driven or a bringing the at least one shear actor or the at least one actor comprising a shear section in contact with the element to be driven.

In addition, in the case of at least three actors arranged on the base element, it is conceivable that the two actors, which lie outer with respect to the arrangement direction, comprise a shear section or are formed as a shear actor, and that the at least one actor arranged between the outer actors comprises a stroke section or is formed as a stroke actor. In this case, the actor or the stroke actor comprising the stroke section ensures, by a corresponding change in dimension, independently its lifting off from the element to be driven or its contacting with the element to be driven.

In addition, it may be advantageous that the actors comprise or consist of an electromechanical material and preferably a piezoelectric and particularly preferably a piezoceramic material. Such actors can be operated with very high dynamics and are particularly suitable for applications for which drive devices with magnetic or magnetizable parts are not suitable.

Furthermore, it may be advantageous that the actors comprise the shape of a column with substantially identical height, preferably with the same cross-sectional geometry. The cross-sectional area of the column is preferably square, although circular or rectangular cross-sections are also conceivable. In addition, it is conceivable to design the actors in the form of hollow cylinders. All this allows a comparatively simple production and assembly with simultaneously optimized or maximized actuating movements.

In addition, it may be advantageous if the drive device comprises a pretensioning device by which each drive element is pressed toward or against the runner in the direction of the runner, so that the contact actor of the respective drive element is in contact with the runner in an electrically non-actuated state, i.e., an inactive or passive state of all actors of this drive element. As a result, in an electrically non-actuated state of the drive device there is self-locking, on the basis of which the runner remains stable at its last approached position, which is advantageous in particular with a perpendicular arrangement of the drive device.

In this case, it may be advantageous if the pretensioning device is designed in such a way that a separate, independent and defined compressive force can be applied to each of the drive elements, by means of which pressure force the latter is pressed toward the runner or against the runner. In this case, it is possible to apply different high pressure forces to the individual drive elements, depending on the requirement and application. In this case, it may be of particular advantage if the drive device comprises a number of separately present prestressing elements corresponding to the plurality of drive elements, and if a prestressing element, for example a compression spring, is assigned to each drive element, wherein the compression spring in turn is supported on a higher-level structure. However, it is also conceivable that a plurality of prestressing elements act on each drive element. It is also conceivable that a different number of prestressing elements acts on different drive elements.

As a result of the above-described provision of separate pretensioning elements, each of which is assigned to a single drive element, and the pretensioning force, which thus acts on each individual drive element and which is well-defined as described above, it is possible for each drive element by actuating the stroke actor or the stroke actors separately to move the contact actor(s) in a direction which is substantially opposite to the direction of the pressing force or the compressive force generated by the respective pretensioning element. This facilitates in particular the assembling of the drive device, since the element to be driven can thus be easily inserted or inserted.

Furthermore, it may be advantageous if the drive unit is arranged on the base in such a way that at least one of the actors of a drive element is fixedly connected to the base and the contact actor is arranged opposite the runner. In this case, it may be of particular advantage that a bearing device is arranged on or in the base, via which bearing device the runner is mounted so as to be movable at least in or along the movement direction. Such a construction is particularly compact and comparatively simple to assemble.

In addition, it may be advantageous for the drive device to comprise two drive units which are arranged on opposite or different sides of the base and the runner is situated between the two drive units. Thus, a significantly greater number of driving actors or contact actors can act on the runner, and this on or from opposite sides, as a result of which higher driving forces can be realized. Due to the resulting lower bearing forces, the bearing of the runner is also simplified.

The invention also relates to a method for operating the above-described drive device having at least two drive element groups, wherein each drive element group comprises at least one drive element. In this case, the respective actors of the first and the second drive element group are electrically controlled in a phase-shifted manner with respect to one another so that their contact actors come into frictional contact with the runner in a temporally offset manner and thereby one after the other with regard to time ensure a drive movement of the runner. As a result, a so-called walk drive can be realized, and a quasi-continuous movement of the runner is made possible by repeated execution. It is conceivable to design the phase offset such that the contacting of a contact actor of a drive element of a drive element group takes place only after the occurrence of getting out of contact of a contact actor of a drive element of another drive element. By contrast, a phase offset can be advantageous which is defined such that a temporal overlap of the contact phases of the contact actors of different drive element groups occurs, wherein a very short time overlap is particularly advantageous.

The invention also relates to and alternatively to a method for operating the above-described drive device comprising at least two drive element groups comprising in each case at least one drive element, wherein the respective actors of the first and the second drive element group are electrically controlled in such a way that their contact actors, in the case of existing frictional contact with the runner, perform a movement in the same direction and, as a result, simultaneously ensure a drive movement of the runner. By means of this type of control, in particular when piezoelectric actors are used, minimum and high-precision drive movements of the runner can be realized.

### DESCRIPTION OF DRAWINGS

The description of embodiments of the drive device according to the invention with regard to the corresponding figures follows, wherein the same reference numerals refer to equal parts of the different figures.

FIG. 1: perspective representation of a drive device according to the invention

FIG. 2: perspective representation of a further drive device according to the invention

### DETAILED DESCRIPTION

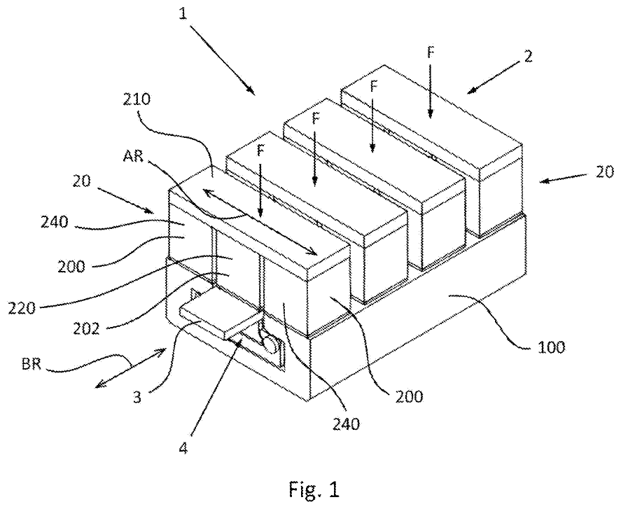

FIG. 1 shows a first embodiment of a drive device 1 according to the invention. On a base 100, four identically designed drive elements 20 are arranged next to or behind one another and are arranged so as to overlap one another. Each of the four drive elements 20 comprises three piezoelectric actors 200 in the form of a column having a square cross section, wherein the columns have substantially the same geometry and in particular the same height. The three actors of each drive element 20 are each arranged on a common plate-shaped base element 210, the length of which is significantly greater than its width or its height or thickness. Each drive element (20) thus comprises a separate and separate base element (210), wherein each base element 210 is arranged opposite and spaced apart from the base 100 so that the three actors 200 are located between the respective base element 210 and the base 100.

Along the longitudinal extension direction of the base element 210, the actors 200 are arranged linearly or in series next to or behind one another and in mutual overlap with respect to one another in such a way that an actor designed as a shear actor 220 is situated between the two outer actors embodied as stroke actors 240. In this case, the corresponding arrangement of the actors defines an arrangement direction AR which is arranged parallel to or coincides with the longitudinal extension direction of the plate-shaped base element 210.

The shear actors 220 of the four drive elements 20 are each arranged opposite an element to be driven 3 in the form of an elongated plate, and the direction of the arrangement one behind the other or of the side-by-side arrangement of the shear actors 220 is parallel to the longitudinal extension direction of the element to be driven 3. The element to be driven 3 is mounted linearly movably along the movement direction BR by means of a bearing device 4 arranged within the base 100 or integrated therein.

By means of prestressing elements of a pretensioning device that are not shown in FIG. 1, each drive element 20 is pressed separately or individually in the direction of the element to be driven 3 or in the direction of the base 4 (indicated by a force arrow F in FIG. 1). Thus, a total of four separately present prestressing elements press the respective drive element 20 with a defined force in the direction of the element to be driven 3, as a result of which contact of the respective shear actor 220 with the element to be driven 3 is ensured at least in the unactuated state of the actors of a drive element 20.

In an operating mode of the drive device 1 according to FIG. 1, the drive elements 20 are controlled or actuated pairwise in-phase, i.e. the actors 200 of the foremost drive element 20 in FIG. 1 and the actors 200 of the third drive element 20 when viewed from the front (wherein the term “front” refers to the side of the drive device 1 of FIG. 1, at which the bearing device 4 or the element to be driven 3 can be seen), which form a first drive element group, are controlled in-phase, i.e. with identical electrical signals, so that the actors of this pair of drive elements move identically and simultaneously. Likewise, the actors 200 of the second drive element 20 when viewed from the front and the actors 200 of the rearmost drive element 20, which form a second drive element group, are controlled in-phase, but with electrical signals which have a phase shift with respect to the electrical signals with which the actors of the first drive element group are controlled.

Starting from the state in which all actors of the drive device 1 are not actuated or not controlled, the actors of the drive elements are controlled in such a way that, with respect to the first (or the second) drive element group, the outer stroke actors 240 perform a longitudinal extension and expand in a direction which extends transversely to the drive or movement direction BR of the element to be driven 3. As a result, the base element 210 and therewith the shear actor 220, which is arranged between the two stroke actors and likewise fixedly connected to the base element 210, moves in a direction pointing away from the element to be driven 3 or away from the base 100, wherein the stroke actors 240 have to overcome the pressing force of the respective pretensioning element of the pretensioning device. As a result, the respective shear actor 220 is lifted off the element to be driven 3.

As a result of the phase-shifted actuation of the actors of the second (or of the first) drive element group, their shear actors 220 begin, at the latest at the time of lifting the shear actors 330 of the respective other drive element group, with the execution of a shear deformation or a shear movement which extends parallel to the drive or movement direction BR of the element to be driven or coincides therewith. Due to the contact of the shear actors of this drive element group with the element to be driven 3, their shear movement or shear deformation results in a drive movement or a drive step of the element to be driven.

In the state of the maximum possible shear deformation or already prior to this time, the associated lift actors 240 of the respective drive element 20 are controlled in such a way that they perform a linear expansion and thereby effect a lifting off of the shear actor 220 which is arranged between them and which is deflected. In the lifted state, the shear actors 220 are controlled in such a way that the shear deformation is back-formed or a shear deformation occurs in a direction which runs opposite to the drive direction BR or opposite to the movement direction BR.

During the corresponding return phase or withdrawal phase of the shear actors of a drive element group, in an analogous manner, the shear actors of the respective other drive element group are controlled in such a way that they perform a shear deformation or a shear movement in the drive or movement direction BR. Since the shear actors of this drive element group in the meantime—i.e., after the initial lift-off phase—by back-formation of the longitudinal deformation of the stroke actors are again in contact with the element to be driven 3, the shear movement of the shear actors of this drive element group now in turn causes a drive movement or a drive step of the element to be driven.

Thus, the two pairs of drive elements or the drive elements of the two drive element groups change—as a result of the phase-shifted actuation of their actors—alternate with each other in the exertion of a drive movement or drive step, and a successive sequence of individual drive steps results in a substantially continuous movement which is limited only by the length of the element to be driven.

In this case, it is possible to operate with different phase offsets. A control method is preferred in which an overlap of the drive movements caused by the shear actors of the two drive element groups exists. This means that the shearing actors of a drive element group, which have just terminated a return movement or withdrawal movement, come into contact with the element to be driven, while the drive step of the shear actors of the respective other drive element group is not yet been completed. An uninterrupted drive of the element to be driven is thus ensured. In this case, the duration of the overlap can be varied and adapted to the specific application case.

Due to the successive sequence of individual drive steps by the two drive element groups, which are similar to the locomotion of living beings by means of leg pairs, such drives are also referred to as walk drives and/or in the corresponding operating mode of walk mode.

A drive device with two drive element groups, each of which comprise only one drive element 20, is also possible. Besides, it is conceivable that, in the case of two drive element groups, each of these comprises more than two drive elements. Irrespective of the number of drive elements per drive element group, the above-described phase-shifted and two-phase control is advantageous in the case of two drive element groups. It is furthermore conceivable to provide more than two drive element groups with at least one drive element in each case, and, in the case of three drive element groups, for example to apply a three-phase control of their respective actors. Finally, it is conceivable to form a drive device with only one drive element.

In a further operating mode of the drive device 1 according to FIG. 1, the actors of all the drive elements 20 are controlled in-phase, so that during the drive phase all four shear actors 220 are in contact with the element to be driven 3 and carry out a movement in the same direction of an analogous movement so that they jointly and simultaneously drive the element to be driven, wherein only a single and common drive step with a very small step size but very high resolution can be realized. This mode of operation is also called analog mode.

Any combinations of the two operating modes outlined above are conceivable, for example initially and at a large distance from the intended position (setpoint position) or from the intended adjustment travel with respect to the element to be driven, to apply the walk mode in order to switch to the analog mode when a position is reached close to the setpoint position.

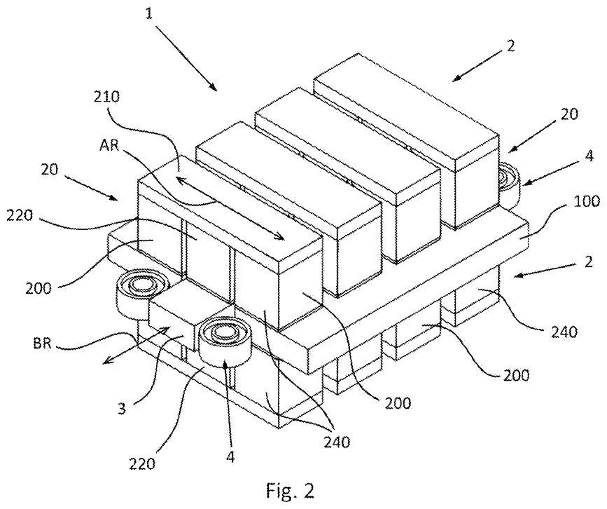

FIG. 2 shows a further embodiment of a drive device 1 according to the invention. The same differs from the embodiment according to FIG. 1 essentially in that, in this case, two drive units of the drive units 2 described with FIG. 1 are provided. Since the construction or structure thereof has already been described in detail with respect to embodiment 1, the detailed description thereof is omitted at this point.

The two drive units 2 lie opposite one another in a mirror-symmetrical arrangement, wherein the element to be driven 3 is situated between them. The plate-shaped base 100, to which the stroke actors 240 of the drive elements 20 are respectively connected, is also arranged between the two drive units 2. The element to be driven 3 in the form of a flat bar is arranged opposite the shear actors 220, and a bearing device 4 outside the base 100 ensures the linear mobility of the element to be driven 3 along or in the movement direction BR. In this case, the thickness of the element to be driven 3 corresponds substantially to the thickness of the plate-shaped base 100, wherein the element to be driven 3 is arranged between two sections of the base 100 and spaced apart therefrom.

### LIST OF REFERENCE SIGNS

1: drive device
2: drive unit
3: element to be driven
4: bearing device
20: drive element (of the drive unit 2)
100: basis
200: actor (of the drive element 20)
202: contact actor (of the drive element 20)
210: base element (of the drive element 20)
220: shear section (of an actor 200)
240: stroke section (of an actor 200)
BR: movement direction (of the element to be driven 3)
AR: arrangement direction (with respect to the actors 200)

1-15. (canceled)

16. A drive device comprising a base, at least one drive unit arranged on the base and comprising at least two drive elements, and a runner which is to be driven by the drive unit along a movement direction and which is movably supported (BR), wherein each drive element comprises
a separate base element which is arranged opposite the base and is arranged at a distance therefrom, and
at least two actors which are arranged one behind the other on the base element along an arrangement direction (AR) oriented transversely to the movement direction (BR) and whose dimensions can be changed,
of which at least one actor is provided for frictional contact with the runner and represents a contact actor, and
wherein at least one of the actors of a drive element comprises a shear section for carrying out a shear movement transverse to the arrangement direction (AR) of the actors and along or parallel to the movement direction (BR) of the runner, and
wherein at least one of the actors of a drive element comprises a stroke section for carrying out a stroke movement transverse to the arrangement direction (AR) of the actors and transversely to the movement direction (BR) of the runner.

17. The drive device according to claim 16,
wherein the drive device comprises at least two drive element groups comprising in each case at least one drive element,
wherein the drive device comprises a controller which is designed to electrically control respective actors of the first and the second drive element group in a phase-shifted manner with respect to one another, so that their contact actors come into frictional contact with the runner in a temporally offset manner and thereby one after the other with regard to time ensure a drive movement of the runner.

18. The drive device according to claim 16,
wherein the drive device comprises at least two drive element groups comprising in each case at least one drive element,
wherein the drive device comprises at least two drive element groups comprising in each case at least one drive element,
wherein the drive device comprises a controller which is designed to electrically control the respective actors of the first and the second drive element group in such a way that their contact actors perform a movement in the same direction when frictional contact exists with the runner and thereby simultaneously ensure a drive movement of the runner.

19. The drive device according to claim 16, wherein at least three actors are arranged on the base element and wherein the two outer actors of each drive element comprise a stroke section and the at least one contact actor arranged between the outer actors comprises a shear section.

20. The drive device according to claim 16, wherein the actors comprise an electromechanical material.

21. The drive device according to claim 16, wherein the actors have the shape of a column with substantially identical height.

22. The drive device according to claim 16, comprising a pretensioning device with which the drive element is pressed in the direction of the runner, so that the contact actor of the drive element is in contact with the runner in an electrically non-actuated state of all actors of this drive element.

23. The drive device according to claim 21, comprising a plurality of drive elements, wherein the pretensioning device is designed in such a way that a separate and defined compressive force can be applied to each of the drive elements, by means of which pressure force the same is pressed onto the runner.

24. The drive device according to claim 21, wherein the drive unit is arranged on the base in such a way that at least one of the actors of a drive element is fixedly connected to the base and the contact actor is arranged opposite the runner.

25. The drive device of claim 22, wherein the pretensioning means comprises a number of pretensioning members corresponding to the number of drive elements, and wherein a pretensioning member is assigned to each drive element.

26. The drive device according to claim 16, wherein the drive unit is arranged on the base in such a way that at least one of the actors of a drive element is fixedly connected to the base and the contact actor is arranged opposite the runner.

27. The drive device according to claim 16, wherein a bearing device is arranged on the base, via which bearing device the runner is movably supported at least along the movement direction (BR).

28. The drive device according to claim 16, comprising two drive units which are arranged on opposite sides of the base and the runner is situated between the two drive units.

29. A method for operating a drive device,
wherein the drive device comprises a base, at least one drive unit arranged on the base and comprising at least two drive elements, and a runner which is to be driven by the drive unit along a movement direction and which is movably supported (BR), wherein each drive element comprises at least two actors along an arrangement direction (AR) oriented transversely to the movement direction (BR) and whose dimensions can be changed, wherein at least one actor is provided for frictional contact with the runner and represents a contact actor,
wherein drive device comprises at least two drive element groups comprising in each case at least one drive element, wherein the respective actors of the first and the second drive element group are electrically driven in a phase-shifted manner with respect to one another, so that their contact actors come into frictional contact with the runner in a temporally offset manner and thereby one after the other with regard to time ensure a drive movement of the runner.

30. A method for operating a drive device,
wherein the drive device comprises a base, at least one drive unit arranged on the base and comprising at least two drive elements, and a runner which is to be driven by the drive unit along a movement direction and which is movably supported (BR), wherein each drive element comprises at least two actors along an arrangement direction (AR) oriented transversely to the movement direction (BR) and whose dimensions can be changed, wherein at least one actor is provided for frictional contact with the runner and represents a contact actor,
wherein the drive device comprises at least two drive element groups comprising in each case at least one drive element, wherein the respective actors of the first and the second drive element group are electrically controlled in such a way that their contact actors perform a movement in the same direction when frictional contact exists with the runner and thereby simultaneously ensure a drive movement of the runner.
